(19) United States
(12) Patent Application Publication
(10) Pub. No.: US 2013/0063169 A1
(43) Pub. Date: Mar. 14, 2013

(54) EVALUATION BOARD

(71) Applicant: Toshiyuki KUMAGAI, Fukuoka (JP)

(72) Inventor: Toshiyuki KUMAGAI, Fukuoka (JP)

(73) Assignee: Mitsubishi Electric Corporation, Chiyoda-ku (JP)

(21) Appl. No.: 13/477,618

(22) Filed: May 22, 2012

(30) Foreign Application Priority Data
Sep. 8, 2011 (JP) 2011-195691

(51) Int. Cl. G01R 31/40; G01R 21/00

(52) U.S. Cl. 324/750.01

(57) ABSTRACT

An evaluation board for evaluating a power module including a power semiconductor device and a detecting unit for detecting characteristics of the power semiconductor device, comprises: a power source circuit supplying an electric power to the power module; a driving circuit driving the power semiconductor device; a display unit displaying a detected signal inputted from the detecting unit; and a substrate on which the power source circuit, the driving circuit, and the display unit are mounted.

### BACKGROUND OF THE INVENTION

### Field of the Invention

The present invention relates to an evaluation board for evaluating power module, and in particular to an evaluation board for simplifying an evaluation environment and enhancing efficiency of the evaluation.

In recent years, power modules, which is composed of a large number of power semiconductor elements mounted in one module, are applied to inverters and the like (for example, refer to Japanese Patent Application Laid-Open No. 2003-249624). The evaluation board is used for evaluating such power modules.

### SUMMARY OF THE INVENTION

In evaluating a power module, a number of power sources and measuring instruments has been needed to be connected to power modules and evaluation boards. Since cable wirings are complicated and there were fears of misconnecting, the cable wirings has been needed to be checked after connecting. In addition, since a high voltage and a large current are used when a power module is evaluated, the power module and the evaluation board are required to be covered with a plastic cover for safety. For this reason, for connecting the power module and the evaluation board to a plurality of power sources and measuring instruments, cable wirings or measuring probes has been needed to be inserted through the gap of the safety cover. Therefore, due to such a complicated evaluation environment, the preparation has been time consuming.

In view of the above-described problems, an object of the present invention is to provide an evaluation board for simplifying an evaluation environment and enhancing efficiency of the evaluation.

According to the present invention, an evaluation board for evaluating a power module including a power semiconductor device and a detecting unit for detecting characteristics of the power semiconductor device, comprises: a power source circuit supplying an electric power to the power module; a driving circuit driving the power semiconductor device; a display unit displaying a detected signal inputted from the detecting unit; and a substrate on which the power source circuit, the driving circuit, and the display unit are mounted.

The present invention makes it possible to simplify an evaluation environment and enhance efficiency of the evaluation.

Other and further objects, features and advantages of the invention will appear more fully from the following description.

### BRIEF DESCRIPTION OF THE DRAWINGS

FIG. 1 is a block diagram showing an evaluation board and a power module according to the first embodiment of the present invention.

FIG. 2 is a perspective view showing the state in which the evaluation board is connected to the power module having the electric power connector.

FIG. 3 is a side view showing the state in which the evaluation board is connected to the power module having the electric power connector.

FIG. 4 is a perspective view showing the state in which the evaluation board s connected to the power module having the electric power terminals.

FIG. 5 is a side view showing the state in which the evaluation board is connected to the power module having the electric power terminals.

FIG. 6 is a sectional view taken along the line I-II in FIG. 5.

FIG. 7 is a block diagram showing an evaluation board and a power module according to the comparative example.

FIGS. 8 and 9 are drawings showing circuits included in the display unit according to the second embodiment of the present invention.

FIGS. 10 and 11 are diagrams showing the relation between the voltage of the detection signals and the lighting luminous element.

FIG. 12 is a diagram showing the placing order and the lighting color of the luminous element.

FIG. 13 is a block diagram showing the display unit according to the third embodiment of the present invention.

FIG. 14 is a diagram showing the delta wave generated by the delta wave generating unit.

FIG. 15 is a diagram showing the output voltages of the voltage comparing circuit in the case where the detecting signal is the first voltage.

FIG. 16 is a diagram showing the output voltages of the voltage comparing circuit in the case where the detecting signal is the second voltage.

FIG. 17 is a graph showing the relation between the duty of the lighting of the luminous element or the tone of the tone generating unit and the voltage of the detection signals.

FIG. 18 is a block diagram showing a display unit according to the fourth embodiment of the present invention.

FIG. 19 is a diagram showing the output of the oscillating circuit.

FIG. 20 is a block diagram showing an evaluation board and a power module according to the fifth embodiment of the present invention.

FIG. 21 is a perspective view showing an evaluation board and a power module according to the fifth embodiment of the present invention.

### DETAILED DESCRIPTION OF THE PREFERRED EMBODIMENTS

An evaluation board according to the embodiments of the present invention will be described with reference to the drawings. The same components will be denoted by the same symbols, and the repeated description thereof may be omitted.

### First Embodiment

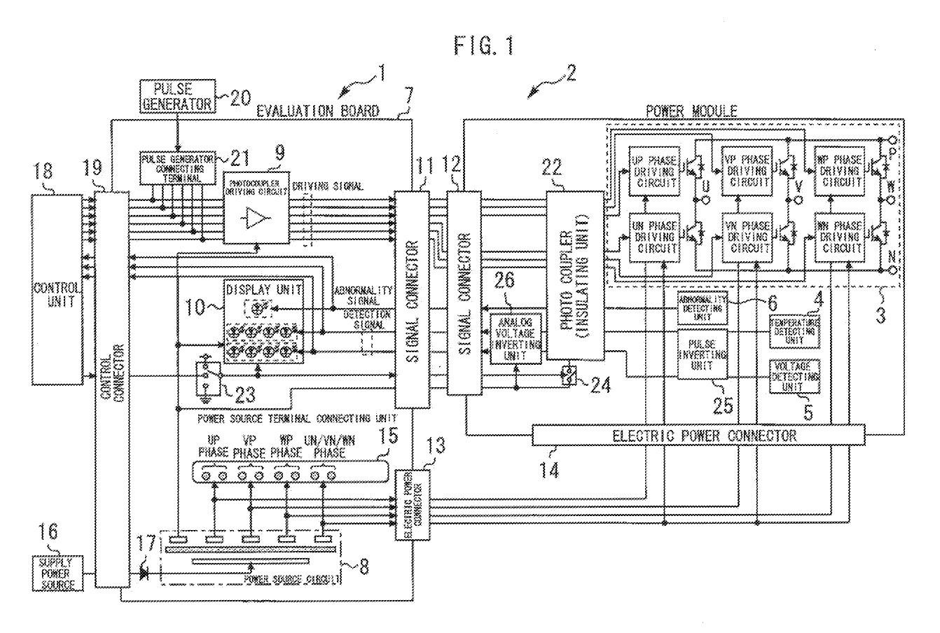

FIG. 1 is a block diagram showing an evaluation board and a power module according to the first embodiment of the present invention. The evaluation board 1 is used for evaluating the power module 2. The power module 2 has a power semiconductor device 3, a temperature detecting unit 4 for detecting the characteristics of the power semiconductor device 3, a voltage detecting unit 5, and an abnormality detecting unit 6. The power semiconductor device 3 is a three-phase inverter having a U phase, a V phase, and a W phase.

On a substrate 7 in the evaluation board 1, a power source circuit 8, a photocoupler driving circuit 9, and a display unit 10 are mounted. The signal connector 11 of the evaluation board 1 is connected to the signal connector 12 of the power module 2. The electric power connector 13 of the evaluation board 1 is connected to the electric power connector 14 of the power module 2, or the power source terminal connecting unit 15 of the evaluation board 1 is connected to the power source terminal of the power module 2 (described below).

The power source circuit 8 generates a plurality of electric powers from a single electric power inputted from the external supply power source 16, and supplies them to each of the U phase, the V phase, and the W phase of the power semiconductor device 3. Additionally, the power source circuit 8 supplies the electric power to the display unit 10 and the photo-coupler driving circuit 9. In order to prevent the breakdown of the evaluation board 1 in case where the source voltage from the supply power source 16 is connected in reverse polarity, a protective diode 17 is connected to the initial stage of the power source circuit 8.

The photo-coupler driving circuit 9 is connected to an external control unit 18 via the control connector 19, and is connected to an external pulse generator 20 via a pulse generator connecting terminal 21. The photo-coupler driving circuit 9 is connected to a photo coupler 22 in the insulating unit of the power module 2 via the connectors for signals 11 and 12, and drives the photo coupler 22 by driving signals to drive the U phase, the V phase, and the W phase of the power semiconductor device 3.

Using changeover switches 23 and 24, the electric power to the photo coupler 22 in the power module 2 is supplied/interrupted so that the U phase, the V phase, and the W phase of the power module 2 are made enabled/disabled. Thereby, erroneous functions such as those seen in the case where driving signals are inputted from the external pulse generator can be prevented. The enabling/disabling is externally set via the control connector 19 of the evaluation board 1 or performed using the internal changeover switches 23 and 24.

The temperature detecting unit 4 of the power module 2 detects the temperature of the power semiconductor device 3, the voltage detecting unit 5 detects the voltage applied to the PN terminal of the power semiconductor device 3, and each of them outputs detection signals.

The detected signals outputted from the temperature detecting unit 4 and the voltage detecting unit 5 are once converted to pulse signals having a pulse width by the pulse inverting unit 25 corresponding to the voltage, and after passing through the insulating unit, demodulated to the analog voltage by the analog voltage inverting unit 26. The demodulated signals are inputted into the display unit 10 of the evaluation board 1. The display unit 10 displays the voltage level of the detected signals inputted from the temperature detecting unit 4 and the voltage detecting unit 5.

In case of overheat or overcurrent of the IGBT in the power semiconductor device 3, or the decrease in the voltage supplied to the U phase, the V case, and the W case of the power module 2, the abnormality detecting unit 6 generates abnormality signals. When abnormality signals from the abnormality detecting unit 6 are inputted, the display unit 10 displays it. Thereby, the operator identifies the abnormality in the display. These abnormality signals may be inputted to the upper control unit 18 via the control connector 19 for controlling the evaluation board 1.

Next, how the evaluation board 1 is connected to the power module 2 will be described. Depending on the shape of the power inputting unit (the electric power connector and the power source terminal) of the power module 2, there are two way of connecting the evaluation board 1 to the power module 2. In any case, however, the evaluation board 1 is placed on the power module 2 via a spacer 27, and the signal connector 11 of the evaluation board 1 is connected to the signal connector 12 of the power module 2 via the cable 28.

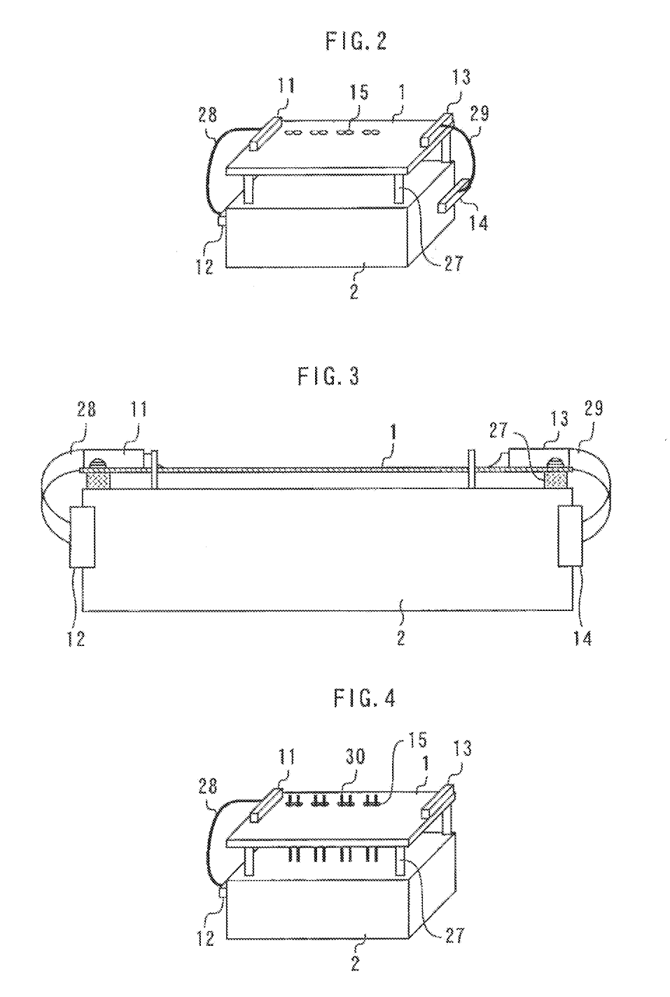

FIGS. 2 and 3 are the perspective view and the side view showing the state in which the evaluation board 1 is connected to the power module 2 having the electric power connector, respectively. The electric power connector 13 of the evaluation board 1 is connected to the electric power connector 14 of the power module 2 via the cable 29.

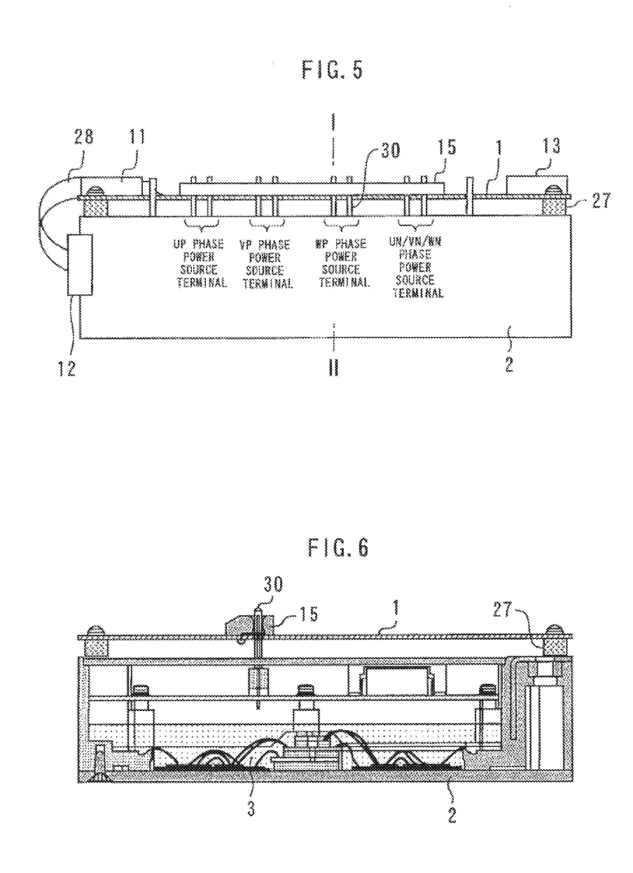

FIGS. 4 and 5 are the perspective view and the side view showing the state in which the evaluation board 1 is connected to the power module 2 having the electric power terminals, respectively. FIG. 6 is a sectional view taken along the line I-II in FIG. 5. The power source terminal 30 of the power module 2 is inserted into the power source terminal connecting unit 15 of the evaluation board 1, and connected thereto.

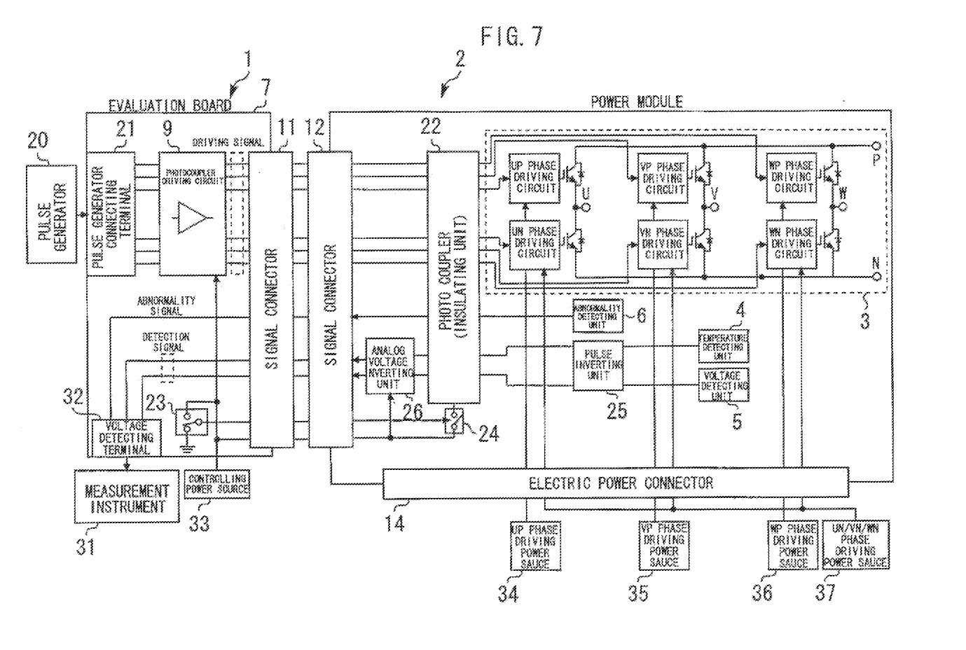

Next, advantages of the present embodiment will be described by comparing with a comparative example. FIG. 7 is a block diagram showing an evaluation board and a power module according to the comparative example. In the comparative example, a measurement instrument 31 such as a voltmeter and an oscilloscope for measuring detection signals and abnormal signals must be connected to the voltage detecting terminal 32 of the evaluation board 1. Furthermore, a controlling power source 33 must be connected to the evaluation board 1, and an UP phase driving power sauce 34, a VP phase driving power sauce 35, a WP phase driving power sauce 36, and a UN/VN/WN phase driving power sauce 37 must be connected to the power module 2. Therefore, the cable wiring is complicated.

In the present embodiment, on the other hand, a power source circuit 8, a photo coupler driving circuit 9, and the display unit 10 required for evaluating the power module 2 are provided on a substrate 7. Thereby, cable wirings can be reduced, and measuring instruments for confirming detection signals from the power module can be eliminated. As a result, the evaluation environment can be simplified, and the evaluation can be more efficient.

Also in the comparative example, since a plurality of power sources are connected to the power module 2, the cable wirings become complicated. In the present embodiment, on the other hand, the power source circuit 8 generates a plurality of electric powers from a single electric power inputted from the outside and supplies them to the U phase, the V phase, and the W phase of the power semiconductor device 3. Therefore, the number of power sources can be reduced, and the cable wiring can be simplified.

Also in the present embodiment, the electric power can be supplied from the power source circuit 8 to the power module 2 through either the electric power connector 13 or the power source terminal connecting unit 15 of the evaluation board 1. Thereby, regardless of the shape of the power inputting unit (the electric power connector and the power source terminal) of the power module 2, the same evaluation board 1, and the standardization of the evaluation board 1 can be provided. Moreover, the generation of errors in the results of measurement due to the individual variability of the evaluation board 1 can be prevented.

Furthermore, in the comparative example, when the power source is failed or when the supply power source 16 is improperly connected to the evaluation board 1, the confirmation of the failure in the power module 2 is difficult, and long time is required for the identification of the cause and the repair. On the other hand, the power source circuit 8 supplies electric power also to the display unit 10 or the photo-coupler driving circuit 9. Therefore, since the power source supply from the power source circuit 8 stops when the power source circuit 8 is failed, or the power source is improperly connected to the evaluation board 1, all the light emitting elements of the display unit 10 are turned off, and abnormality can be easily recognized. Also since the power semiconductor device 3 driven by the photo-coupler driving circuit 9 is disabled in the abnormal state, the breakdown of the power module 2 is prevented, and the safety of the evaluation practitioner can be secured.

### Second Embodiment

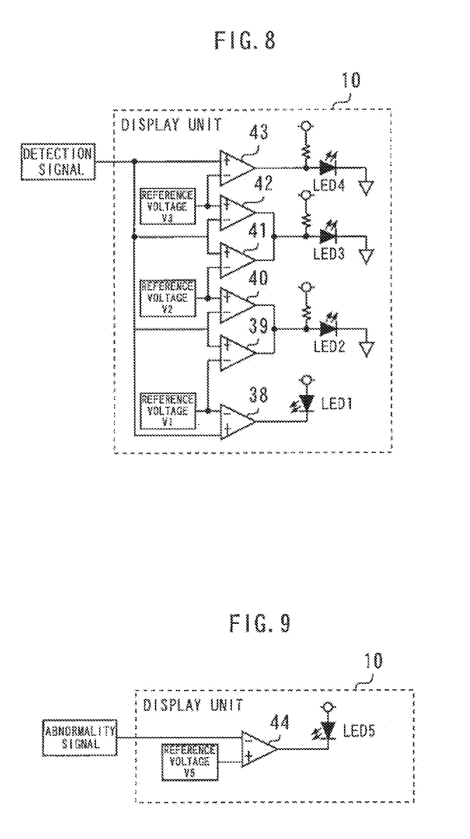

FIGS. 8 and 9 are drawings showing circuits included in the display unit according to the second embodiment of the present invention. The display unit 10 includes two circuits shown in FIG. 8 and a circuit shown in FIG. 9. The circuit shown in FIG. 8 displays the detected signals (analog voltage) from the temperature detecting unit 4 or the voltage detecting unit 5 in the power module 2, and the circuit shown in FIG. 3 displays the abnormal signals from the abnormality detecting unit 6.

The outputs of the voltage comparing circuits 38 to 43 are open collectors, and their outputs can be connected to each other. The voltage comparing circuits 38 to 43 compare the voltage of the detection signals with the reference voltages V1 to V3, and cause the luminous elements LED1 to LED4 corresponding to the voltage range of the detection signals to light up. A voltage comparing circuits 44 compares the voltage of the abnormal signals with the reference voltage V4, and causes a luminous element LED5 to light up.

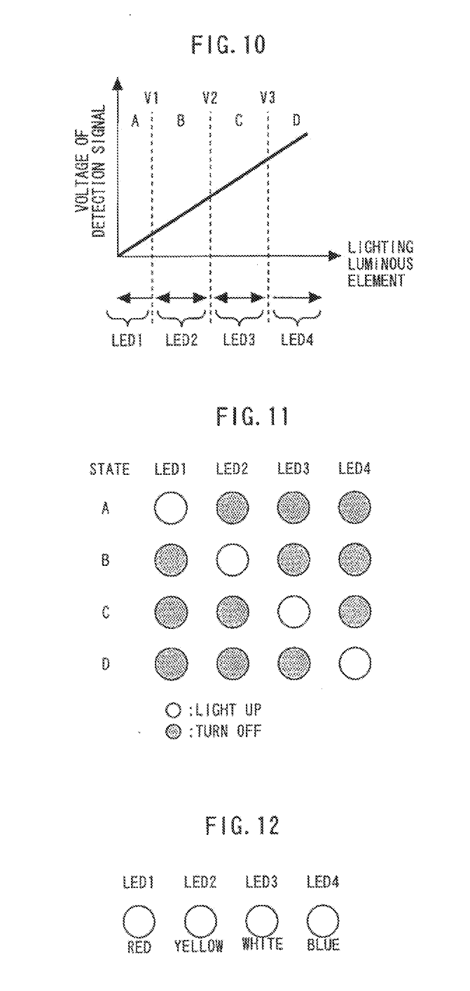

FIGS. 10 and 11 are diagrams showing the relation between the voltage of the detection signals and the lighting luminous element. When the voltage of the detection signal is equal to or below the reference voltage V1, LED1 lights up. When the voltage of the detection signal is between the reference voltage V1 and the reference voltage V2, LED2 lights up. When the voltage of the detection signal is between the reference voltage V2 and the reference voltage V3, LED3 lights up. When the voltage of the detection signal is equal to or above the reference voltage V1, LED4 lights up. FIG. 12 is a diagram showing the placing order and the lighting color of the luminous element. Luminous elements LED1 to LED4 are placed in the order of the corresponding voltage ranges of the detection signals, and have different lighting colors.

As described above, the voltage comparing circuits 38 to 43 compare the voltages of detecting signals and the reference voltages V1 to V3, and LED1 to LED4 corresponding to the different voltage ranges of the detecting signals are lit up. Thereby, since the voltage range of the detecting signals can be confirmed by the luminous elements LED1 to LED4, the measuring equipment for measurement can be eliminated.

In addition, since the luminous elements LED1 to LED4 are arranged in the order of the voltage ranges of the corresponding detection signals on the substrate 7, the results of detection can be easily confirmed. Furthermore, since the luminous elements LED1 to LED4 have different luminescent colors, an excellent visibility can be obtained even if remote confirming via a transparent safety cover.

In the present embodiment, although the voltage range of detection signals is divided in four, it can be further divided by increasing the number of reference voltages. Moreover, by reducing the number of luminous elements to one, the current consumption can be lowered.

### Third Embodiment

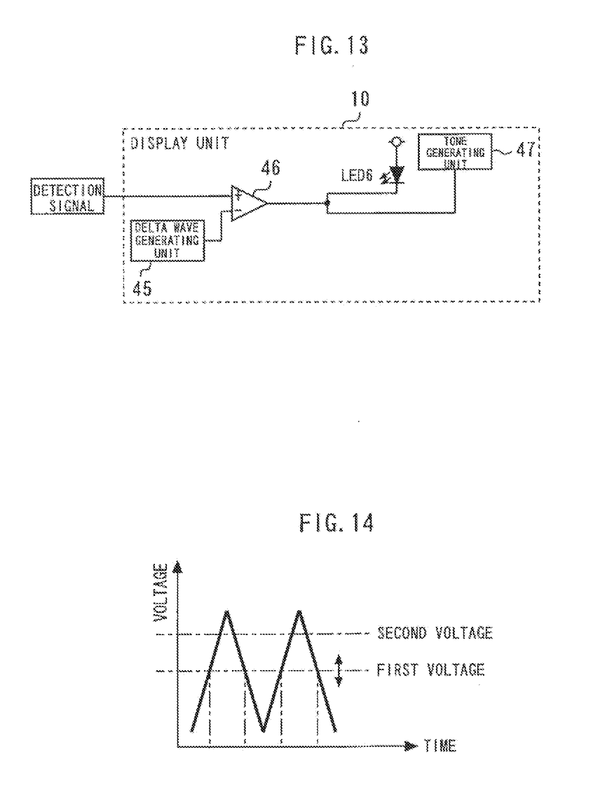

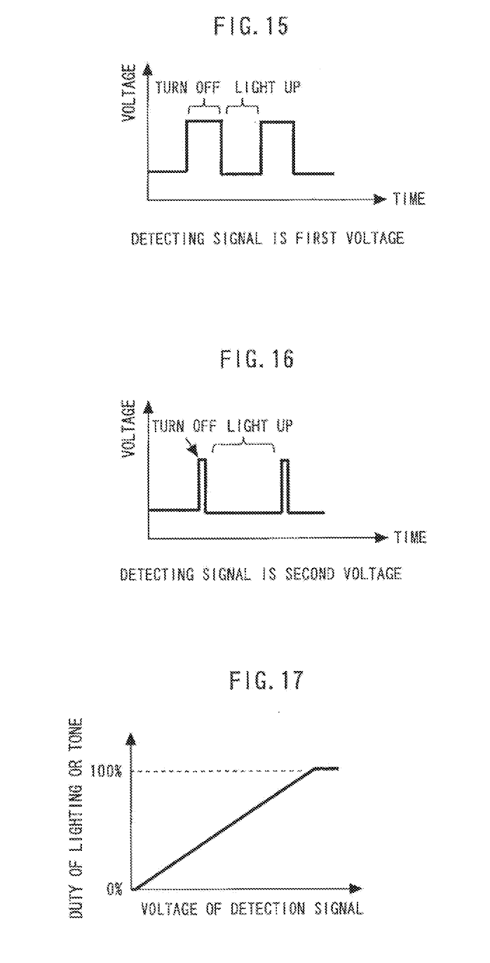

FIG. 13 is a block diagram showing the display unit according to the third embodiment of the present invention. A delta wave generating unit 45 generates delta waves. A voltage comparing circuit 46 compares the voltages of the detecting signal and the voltage of the delta wave, and outputs a square wave. The cycle of the square wave is preferably 1 to 10 seconds. FIG. 14 is a diagram showing the delta wave generated by the delta wave generating unit. FIGS. 15 and 16 are diagrams showing the output voltages of the voltage comparing circuit in the case where the detecting signal is the first voltage, and in the case where the detecting signal is the second voltage, respectively.

Depending on the output of the voltage comparing circuit 46, the luminous element LED6 lights up, and the tone generating unit 47 generates tones. By measuring the duration of lighting or intermittent tones using a watch or the like to determine the duty, the voltage of the detection signals can be recognized. FIG. 17 is a graph showing the relation between the duty of the lighting of the luminous element or the tone of the tone generating unit and the voltage of the detection signals. Thereby, since the voltage range of the detection signals can be confirmed by the luminous element LED6 or the tone generating unit 47, the measuring instruments for measurement become unnecessary. In addition, since one system of the voltage comparing circuit 46 is enough, the circuit configuration becomes simplified.

By using the tone generating unit 47, since the results of detection can be recognized not only visually, but also auditory, the identification of the detected result can be improved. In addition, even if the evaluation board 1 is placed in the place where the luminous element LED6 cannot be visually recognized, the results of detection can be recognized by the tone. Furthermore, one of either the blinking of the luminous element LED6 or the intermittent tone of the tone generating unit 47 may be used.

Moreover, it is preferable that a graph, showing the relation between the duty of the lighting of the luminous element LED6 or the tone from the tone generating unit 47 and the voltage of the detection signals, is printed in the vicinity of the luminous element LED6 using silk printing. Thereby, even if there is no reference material in hand, the results of detection can be known.

### Fourth Embodiment

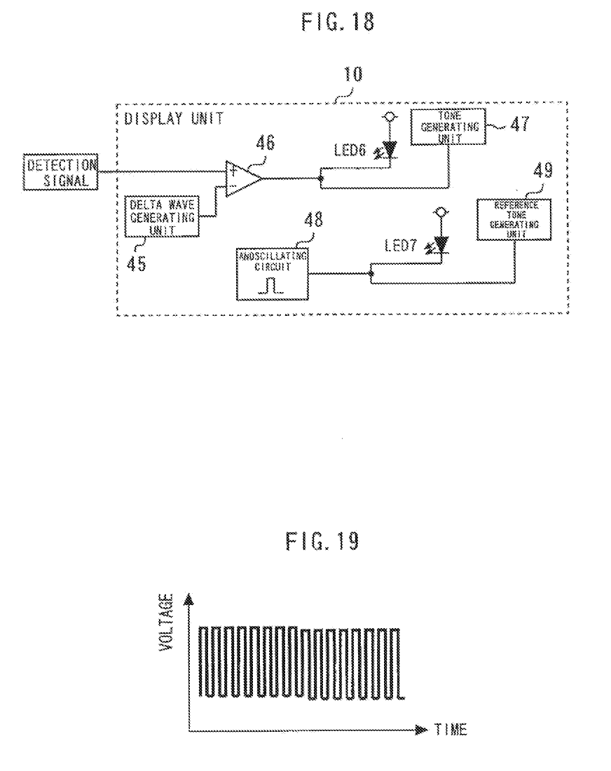

FIG. 18 is a block diagram showing a display unit according to the fourth embodiment of the present invention. In addition to the constitution in the third embodiment, an oscillating circuit 48, a reference light emitting element LED7, and a reference tone generating unit 49 are established.

FIG. 19 is a diagram showing the output of the oscillating circuit. The oscillating circuit 48 outputs a square wave having a constant cycle. Depending on the square waves from the oscillating circuit 48, the reference light emitting element LED7 flashes at constant time interval, and the reference tone generating unit 49 generates tones at constant time interval. The appropriate cycle of the square waves from the oscillating circuit 48 is about 1/10 of the cycle of the delta waves.

By checking the time intervals in the flashing of the luminous element LED6 and the reference luminous element LED7, the confirming accuracy of the test result is improved. In the same manners, by checking the time intervals in the tones of the tone generating unit 47 against the reference tone generating unit 49, the confirmation accuracy of the test result is improved.

### Fifth Embodiment

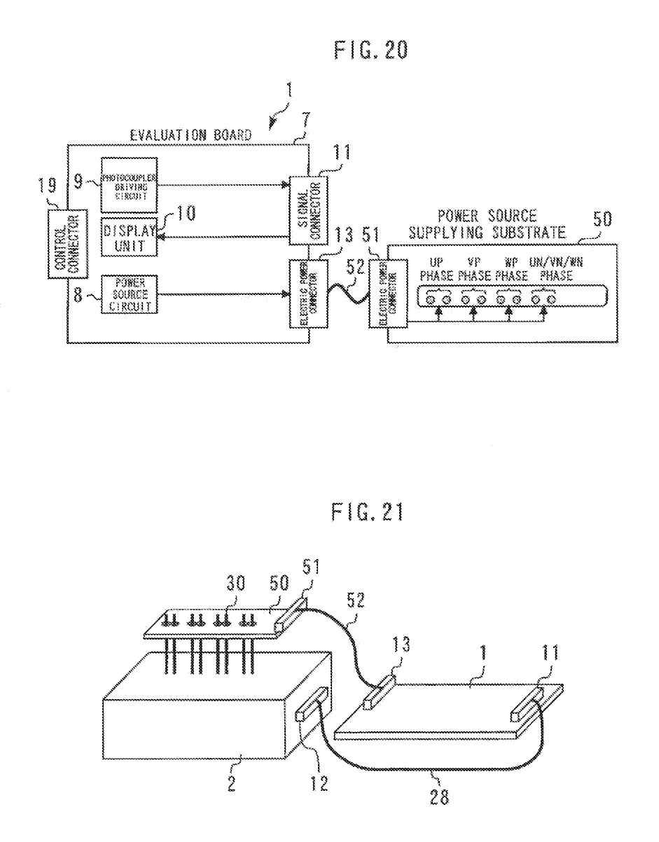

FIGS. 20 and 21 are a block diagram and a perspective view showing an evaluation board and a power module according to the fifth embodiment of the present invention, respectively. In place of the power source terminal connecting unit 15 in the first embodiment, a detachable power source supplying substrate 50 is established on the power source terminal 30 of the power module 2 separating from the substrate 7. The electric power connector 13 of the evaluation board 1 is connected to the electric power connector 51 of the power source supplying substrate 50 via the cable 52.

The power source supplying substrate 50 is connected to the power source circuit 8 on the substrate 7 via connectors for electric power 13, 51 and the cable 52, and supplies the electric power from the power source circuit 8 to the power source terminal 30. Thereby, the substrate 7 can be placed on the side of the power module 2 in the state in which the power source supplying substrate 50 is mounted on the power source terminal 30 of the power module 2. By the effect of the large current flowing in the power module 2, the noise generated in the up and down directions of the power module 2 can be avoided, and the stable evaluation can be performed.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2011-195691, filed on Sep. 8, 2011 including specification, claims, drawings and summary, on which the Convention priority of the present application is based, are incorporated herein by reference in its entirety.

What is claimed is:

1. An evaluation board for evaluating a power module including a power semiconductor device and a detecting unit for detecting characteristics of the power semiconductor device, comprising:
a power source circuit supplying an electric power to the power module;
a driving circuit driving the power semiconductor device;
a display unit displaying a detected signal inputted from the detecting unit; and
a substrate on which the power source circuit, the driving circuit, and the display unit are mounted.

2. The evaluation board according to claim 1, wherein the power semiconductor device is a three-phase inverter having a U phase, a V phase, and a W phase, and
the power source circuit generates a plurality of electric powers from an externally inputted single electric power and supplies the plurality of electric powers to the U phase, the V phase, and the W phase of the power semiconductor device respectively.

3. The evaluation board according to claim 1, further comprising:
a connector connected to an electric power connector of the power module; and
a power source terminal connecting unit connected to a power source terminal of the power module,
wherein an electric power is supplied from the power source circuit to the power module through either the connector or the power source terminal connecting unit.

4. The evaluation board according to claim 1, wherein the power source circuit supplies an electric power to the display unit.

5. The evaluation board according to claim 1, wherein the power source circuit supplies an electric power to the driving circuit.

6. The evaluation board according to claim 1, wherein the display unit includes:
a voltage comparing circuit comparing a voltage of the detection signal with a reference voltage; and
a plurality of luminous elements lighting up corresponding to different voltage ranges of the detecting signal depending on an output of the voltage comparing circuit.

7. The evaluation board according to claim 6, wherein the plurality of luminous elements are placed in the order of the corresponding voltage ranges of the detection signal.

8. The evaluation board according to claim 6, wherein the plurality of luminous elements have different lighting colors.

9. The evaluation board according to claim 1, wherein the display unit includes:
a delta wave generating unit generating a delta wave;
a voltage comparing circuit comparing a voltage of the detecting signal and a voltage of the delta wave; and
a luminous element lighting up depending on an output of the voltage comparing circuit.

10. The evaluation board according to claim 9, wherein a relation between lighting of the luminous element and a voltage of the detection signal is printed in the vicinity of the luminous element.

11. The evaluation board according to claim 9, further comprising a reference light emitting element flashing at constant time interval.

12. The evaluation board according to claim 9, further comprising a tone generating unit generating tone depending on an output of the voltage comparing circuit.

13. The evaluation board according to claim 12, further comprising a reference tone generating unit generating tone at constant time interval.

14. The evaluation board according to claim 1, further comprising a detachable power source supplying substrate established on a power source terminal of the power module, separating from the substrate, connected to the power source circuit on the substrate via a cable, and supplying an electric power from the power source circuit to the power source terminal,
wherein the substrate is placed on the side of the power module in the state in which the power source supplying substrate is mounted on the power source terminal of the power module.
